(19) United States
(12) Patent Application Publication
(10) Pub. No.: US 2012/0174965 A1
(43) Pub. Date: Jul. 12, 2012

(54) SOLAR POWER GENERATOR

(75) Inventors: Yoshinori Miyazaki, Inuyama-shi (JP); Masao Hiramatsu, Inuyama-shi (JP); Masahito Fujita, Inuyama-shi (JP); Kouki Ozaki, Inuyama-shi (JP)

(73) Assignee: DAIDO METAL COMPANY LTD., Nagoya-shi (JP)

(21) Appl. No.: 13/496,624

(22) PCT Filed: Sep. 13, 2010
(86) PCT No.: PCT/JP2010/065755

§ 371 Date: Mar. 16, 2012

(30) Foreign Application Priority Data
Sep. 17, 2009 (JP) 2009-215737

(51) Int. Cl. H01L 31/052

(52) U.S. Cl. 136/246

(57) ABSTRACT

Disclosed is a solar power generator of novel construction. A solar power generator (1) is provided with a base (2) and a solar panel (10) which is rotatable in the circumferential direction. The solar panel (10) is provided with a follower section (11) which makes contact with the base (2). The solar panel (10) rotates with a lower end portion of the follower section (11) in contact with the base (2).

### TECHNICAL FIELD

The present invention relates to a solar power generator and a solar panel used therein.

### BACKGROUND ART

A solar power generator is receiving attention because of need for preservation of ecological systems. The solar power generator has a solar panel, on which photoelectric conversion devices are arranged. In order to improve power generation efficiency, the solar power generator should preferably have a sunlight tracking mechanism that adjusts an azimuth of the solar panel such that the solar panel invariably faces the sun.

The sunlight tracking mechanism includes a one-axis tracking type and a two-axis tracking type. The former type adjusts the azimuth (east-south-west) of the solar panel. The latter type adjusts an angle of elevation, which corresponds to an altitude of the sun, in addition to the azimuth (refer to Patent documents 1 and 2). In both types, the solar panel is supported by a supporting section (rotary shaft) and is used in a state where the entire circumference of the solar panel is floated above the ground or a base of the solar panel.

### PRIOR ART DOCUMENTS

### Patent Documents

Patent document 1: JP-A-2007-258357

Patent document 2: JP-A-2007-19331

### DISCLOSURE OF THE INVENTION

### Problems to be Solved by the Invention

The solar power generator exposed to the weather is required to have high mechanical strength and durability. Specifically, mechanical stress is applied to the supporting section that rotates the solar panel to track the sun. Therefore, high quality is required of a structure and a material of the supporting section.

The two-axis tracking type has a more complicated mechanism, which has been a major factor of increase of a manufacturing cost of the solar power generator. Further, it has been a negative factor to the efforts to realize a maintenance-free and/or long-life solar power generator.

### Means for Solving the Problems

The present invention has been made to solve the above problems. A first aspect of the present invention is defined as follows. That is, a solar power generator has a base and a solar panel rotatable in a circumferential direction. The solar panel has a follower section that contacts the base. The solar panel rotates with a lower end portion of the follower section in contact with the base.

In the thus-defined solar power generator as in the first aspect, a portion (lower end portion) of the follower section of the solar panel is in contact with the base. Therefore, the solar panel is supported by the supporting section (rotary shaft) and the base. Accordingly, the load applied to the supporting section is reduced, so the supporting section can be reduced in size and the structure of the supporting section can be simplified. Thus, the manufacturing cost of the supporting section is reduced and the maintenance of the supporting section becomes less troublesome.

A second aspect of the present invention is defined as follows. That is, in the solar power generator as in the first aspect, a supporting section for azimuth direction tracking is attached to the solar panel, and the solar panel rotates around an attachment position of the supporting section.

In the thus-defined solar power generator, the solar panel is rotated around the attachment position of the supporting section. Therefore, the supporting section functions also as a rotational force applying device. Accordingly, the device can be simplified.

A third aspect of the present invention is defined as follows. That is, in the solar power generator as in the second aspect, one end of the supporting section is attached to the base rotatably, and the other end of the supporting section is attached to the solar panel at a position deviated from the center of the solar panel.

In the thus-constructed solar power generator according to the third aspect, the other end of the supporting section (i.e., end attached to solar panel) swings around the one end of the supporting section (i.e., end attached to base) to follow the sun. The attachment position of the other end serves as a rotation center of the solar panel. The attachment position of the other end is deviated from the center of the solar panel. If the rotation center of the solar panel is deviated from the central position in this way, a distance L from the peripheral portion of the solar panel, which contacts the base, to the rotation center changes with the rotation. Even if length F of the supporting section (i.e., distance between one end attached to base and other end attached to solar panel) is fixed, an elevation angle of the solar panel changes with the change of the distance L (as shown in FIGS. 1, 2 and 5 and as explained in more details in description of embodiments).

A fourth aspect of the present invention is defined as follows. That is, in the solar power generator as in the second or third aspect, the supporting section applies a rotational force to the solar panel. Thus, a component can be commonly used as the supporting section and the rotational force applying member, so the solar power generator can be simplified.

A fifth aspect of the present invention is defined as follows. That is, in the solar power generator as in any one of the first to fourth aspects, a peripheral portion of the solar panel serves as the follower section.

By using the peripheral portion of the solar panel as the follower section, a lowermost end portion of the solar panel is supported by the base, so the support of the solar panel is stabilized.

When the peripheral portion is used as the follower section, it is preferable that a reinforcement section having wear resistance is formed in a range of the peripheral portion that contacts the base (sixth aspect).

Thus, even if the solar panel is rotated, the peripheral portion of the solar panel becomes less apt to wear because the peripheral portion is reinforced with the reinforcement section, whereby the lifetime lengthens. Accordingly, requirement for a maintenance-free system can be responded.

From a viewpoint to secure smooth rotation of the solar panel, the solar panel should preferably have a round plate shape or an elliptical plate shape (seventh aspect).

### BRIEF DESCRIPTION OF THE DRAWINGS

FIG. 1 is a perspective view showing a solar power generator 1 according to an embodiment of the present invention.

FIG. 2 is a view showing an attitude of the solar power generator 1. FIG. 2(A) shows a state where a solar panel faces the south. FIG. 2(B) shows a state where the solar panel faces the east. FIG. 2(C) shows a state where the solar panel faces the west.

FIG. 3 is a cross-sectional view showing an example of a connecting structure between a supporting bar 21 and a solar panel 10.

FIG. 4 is a schematic view showing a contact mode between a base 2 and a peripheral portion of the solar panel 10.

FIG. 5 is a schematic diagram illustrating change of an elevation angle of the solar panel 10.

FIG. 6 is a graph indicating a power generation efficiency of the solar power generator 1 according to the embodiment.

FIG. 7 is a schematic diagram illustrating a mode for rotating the solar panel 10.

FIG. 8 is a side view showing a solar power generator according to another embodiment.

FIG. 9 is a side view showing a solar power generator according to yet another embodiment.

### MODES FOR CARRYING OUT THE INVENTION

Hereinafter, the present invention will be explained in more details based on embodiments.

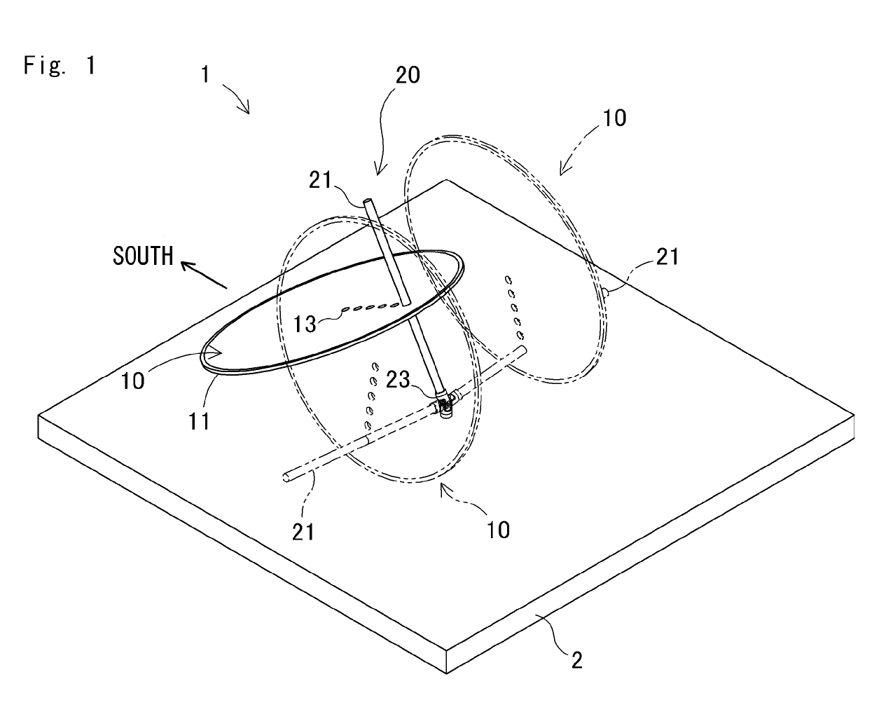

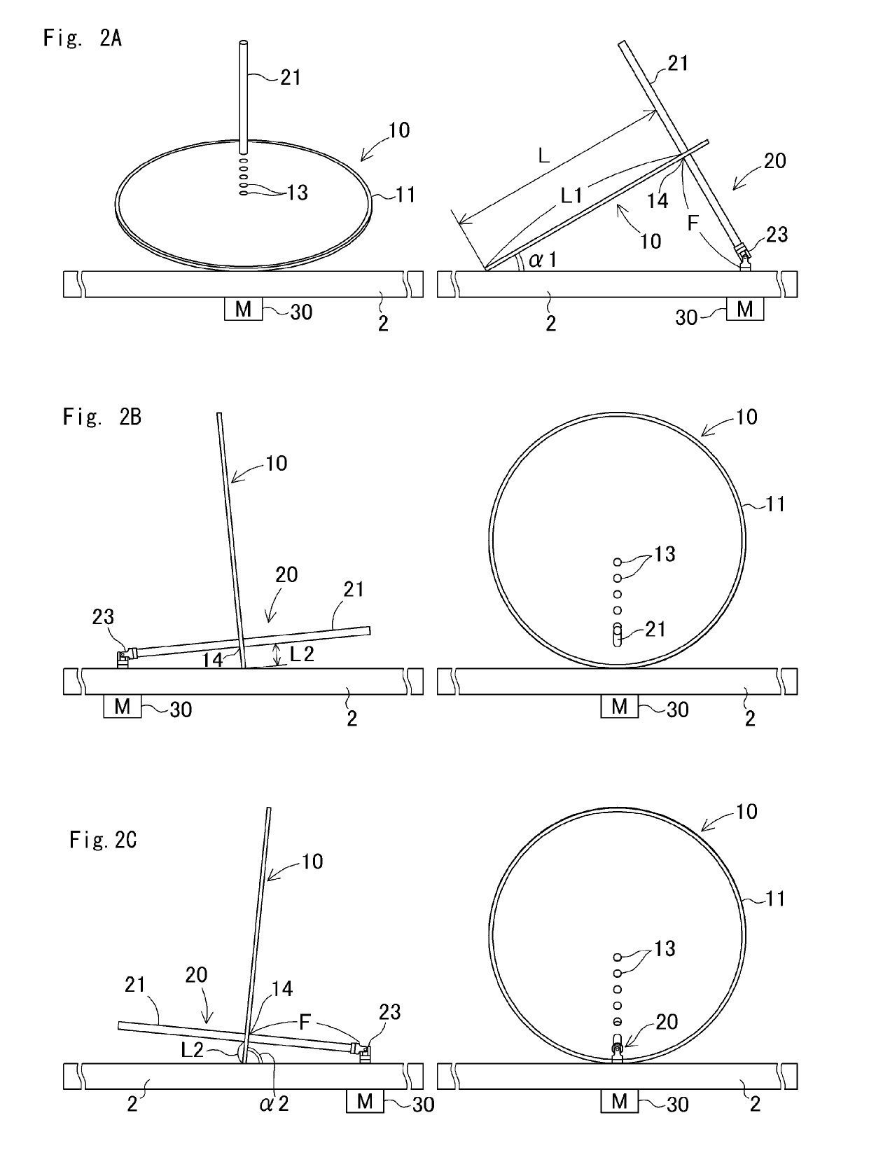

FIG. 1 is a perspective view illustrating an operation of a solar power generator 1 according to the embodiment. FIG. 2 shows front views and side views of the same. FIG. 2(A) shows a front view and a right-side view at the time when the solar power generator 1 faces the south. FIG. 2(B) shows a front view and a right-side view at the time when the solar power generator 1 faces the east. FIG. 2(C) shows a front view and a right-side view at the time when the solar power generator 1 faces the west.

As apparently understood from these drawings, the solar power generator 1 has a base 2, a solar panel 10 and a supporting section 20.

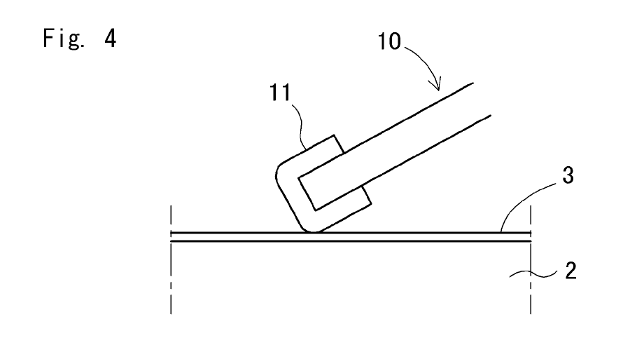

The base 2 is a base plate supporting the solar panel 10 and the supporting section 20. In this example, the round solar panel 10 rolls over a surface of the base. Therefore, the surface of the base plate is formed flat. In order to reduce rotation resistance of the solar panel 10 and to suppress wear of the surface, the surface of the base 2 should be preferably reinforced by a reinforcement layer 3 (refer to FIG. 4). The reinforcement layer 3 can be formed by a metallic material, a synthetic resin material or an inorganic material having high weather resistance and high wear resistance.

The shape of the base 2 can be designed arbitrarily as long as the base 2 can support the rotation of the solar panel 10. The base 2 in the shape of a rectangular flat plate is employed in the illustration but the base 2 in a round shape or a polygonal shape other than the rectangular shape may be used. The surface of the base 2 is not limited to the flat shape. Concavity and convexity may be provided on the surface of the base 2 in a range where the rotation of the solar panel is not interfered.

The base 2 may be divided into a portion for supporting the solar panel 10 and a portion for supporting the supporting section 20.

It is preferable that the base 2 has three or more leg sections having adjustable lengths to enable adjustment of height of the base 2 and to secure levelness of the base 2.

Photoelectric conversion elements, i.e., photovoltaic elements, are arranged on the solar panel 10. An arbitrary type of the photovoltaic element can be used. In the drawing, a device for collecting electricity generated by the respective photovoltaic elements and a device for transmitting or storing the electricity are not shown.

In the embodiment, recess portions (multiple through holes 13 in this example) are formed in the solar panel 10. The through holes 13 are deviated from the center of the solar panel 10. The through holes 13 are formed at equal pitches on a virtual line of a radius extending from the center to an outer periphery. A supporting bar 21 of the supporting section 20 penetrates through the through hole 13. Positions for forming the through holes 13 are not limited to the positions of equal pitches.

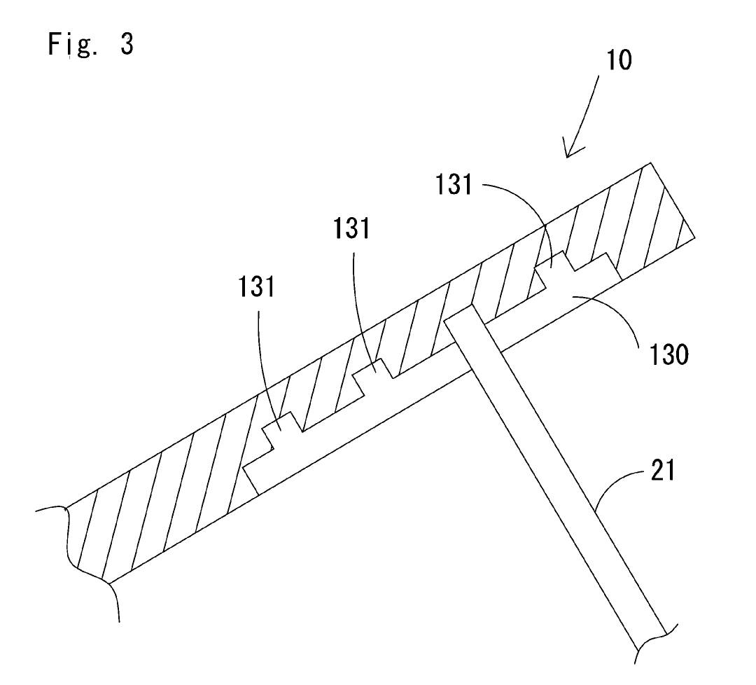

As an example of the recess portion, the through holes 13 may be connected with each other and made into a slit-like shape. As another example of the recess portion, a groove 130 having a bottom may be provided on a side of the solar panel 10, on which the photovoltaic elements are not arranged, as shown in FIG. 3. The groove 130 extends from the center to an outer peripheral side, and a tip end of the supporting bar 21 fits into the groove 130. In the case of the groove-like shape, the optimum position of the supporting bar 21 for an installation site, the season and the like can be set arbitrarily. Even if the supporting bar 21 is movable, the structure can be made simple and highly stable since the supporting bar 21 fits into the groove 130. In order to stabilize the fitting position of the supporting bar 21 more, a hole 131 having a bottom may be formed in the bottom portion of the groove 130 and the tip end of the supporting bar 21 may be fitted to the hole 131.

In the present embodiment, a reinforcement section 11 is attached to the peripheral portion of the solar panel 10 (see FIG. 4). The reinforcement section 11 may be made of a metal material, a synthetic resin material or an inorganic material having excellent weather resistance and wear resistance. Uplift of the solar panel 10 can be prevented effectively by ensuring sufficient weight of the reinforcement section 11, e.g., by setting the specific gravity of the reinforcement section 11 to be larger than the specific gravity of a main body portion of the solar panel 10.

In the case where the solar panel 10 is constructed to rotate with its peripheral portion in contact with the surface of the base 2, the solar panel 10 should be preferably formed in the shape of a round plate or an elliptic plate in order to reduce rotation resistance. However, a polygonal shape is not excluded if it is rotatable. An elevation angle can be controlled also by the shape of the peripheral portion. The shape of the round plate or the elliptic plate provides high smoothness of rotation. Therefore, such the shapes can effectively inhibit the mechanical stress from acting on the supporting section 20 and the like.

The supporting section 20 has the supporting bar 21 and a rotation mechanism such as a universal joint 23. In the case where the through hole 13 is provided, the supporting bar 21 is inserted into an arbitrary through hole 13 of the solar panel 10 and is fixed at a predetermined position. A fixing method is not limited specifically. For example, a thread groove may be formed on a peripheral surface of the supporting bar 21 and a pair of nuts may be screwed to the supporting bar 21, thereby pinching the solar panel 10 with the nuts.

The elevation angle α of the solar panel 10 can be set by selecting the through hole 13 for the insertion and by selecting the length of an effective portion 21v of the supporting bar 21 inserted into the through hole 13.

In this case, it is preferable that the supporting bar 21 can be extended and contracted. If the length of the supporting bar 21 is shortened, the solar panel 10 can be set horizontal to the installation site easily. Alternatively, the solar panel 10 may be set horizontal to the installation site by taking the tip end of the supporting bar 21 off the recess portion 13. From the viewpoint of installation, the structure in which the supporting bar 21 does not protrude from the solar panel 10 in any situations is preferable.

In the present embodiment, the lower end portion of the supporting bar 21 is fixed to the universal joint 23. Thus, the supporting bar 21 can be oriented at an arbitrary angle in 360 degrees around the universal joint 23. The universal joint 23 is arranged at the center of the base 2. The arrangement position of the universal joint 23 to the base 2 can be selected arbitrarily.

The universal joint 23 is linked with a rotary shaft of a motor 30, which is a rotational force applying member. Thus, the rotational force of the motor 30 is transmitted to the supporting bar 21, and the solar panel 10 rotates with the rotation of the supporting bar 21. Arrangement positions of the base 2, the solar panel 10, the supporting bar 21, the motor 30 and the like may be selected arbitrarily as long as the solar panel 10 can be rotated.

Change of the elevation angle α of the solar panel 10 accompanying the rotation of the solar panel 10 will be explained based on FIGS. 1, 2 and 5.

First, an attitude of the solar panel 10 at the time when the sun is at the culmination is shown in FIG. 2(A). The elevation angle at that time is denoted with α1. The supporting bar 21 is fixed to the solar panel 10 substantially perpendicularly and the angle therebetween does not change substantially. In this embodiment, a distance F from a fixed portion (other end) of the supporting bar 21 in the through hole 13 to a lower end (one end) of the supporting bar 21 linked to the universal joint 23 (this portion will be referred to as “effective portion 21v” herein) is fixed.

If the supporting bar 21 is rotated clockwise in FIG. 1 from the state of FIG. 2(A), the solar panel 10 moves westward to follow an azimuth of the sun. A state where the solar panel 10 faces the due west is shown by an imaginary line in FIG. 1 and is shown in the front view and the side view in FIG. 2(C). In each of FIGS. 2(A), 2(B) and 2(C), the front view is drawn along the direction to view the north from the south, and the side view is drawn along the direction to view the west from the east.

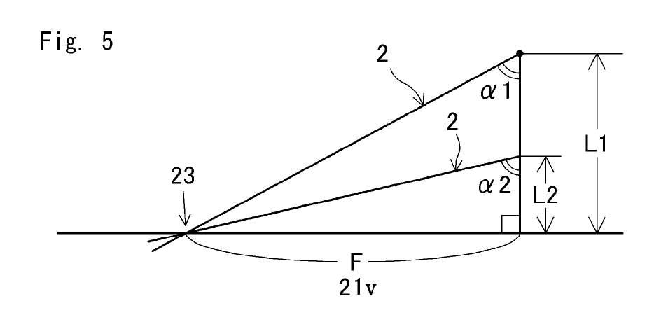

As apparently understood from the drawings, when the length F of the effective portion 21v of the supporting bar 21 is fixed and the angle between the supporting bar 21 and the solar panel 10 is fixed, a distance L from a connection 14 (through hole 13) between the supporting bar 21 and the solar panel 10 to the peripheral portion of the solar panel 10 changes with the rotation of the solar panel 10. Relationships among the distance L (L1: when facing south, L2: when facing west or east), the length F of the effective portion 21v of the supporting bar 21 and the elevation angle α are schematically shown together in FIG. 5.

The distance L from the connection 14 (through hole 13) between the supporting bar 21 and the solar panel 10 to the peripheral portion of the solar panel 10 may be maximized when the solar panel 10 faces the south. That is, the connection 14 (through hole 13) between the supporting bar 21 and the solar panel 10 may be set at the highest position when the solar panel 10 faces the south. With such the construction, the solar panel 10 rises up and its elevation angle increases when the solar panel 10 faces the west as understood from FIGS. 1, 2 and 5.

On the same conditions, the elevation angle of the solar panel 10 increases also when the solar panel 10 faces the east (see FIG. 2(B)).

Even if the elevation angle at the time when the solar panel 10 faces the south is set in accordance with the sun culmination altitude such that an angle of incidence of the sunlight to the solar panel 10 is set at substantially the right angle, there is a case where the angle of incidence to the solar panel 10, which rises up while rotating, does not become the right angle thereafter. However, it is apparent that the power generation efficiency improves as compared to the case where the elevation angle of the solar panel 10 is constant in the all directions (i.e., one-axis tracking type).

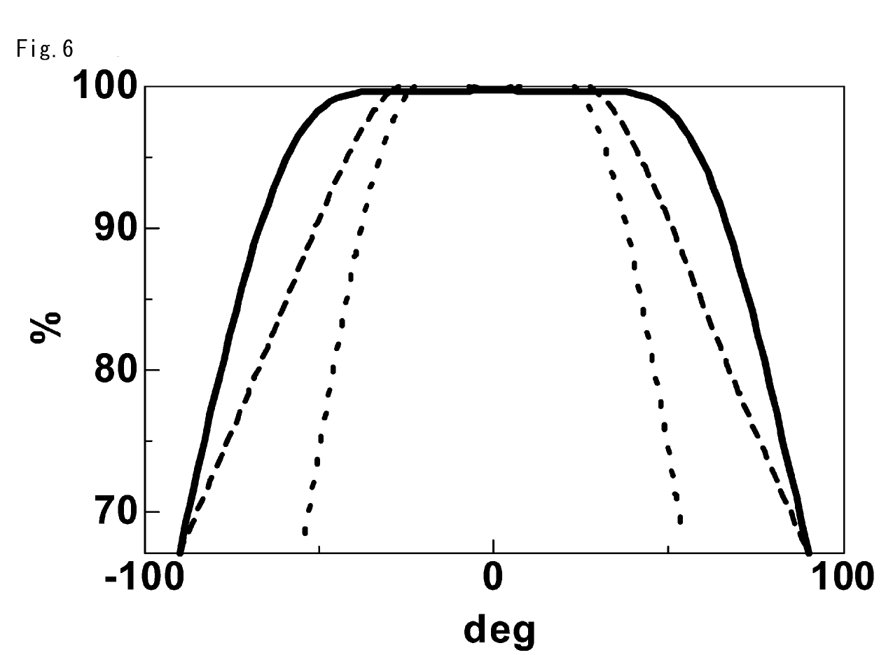

Results of the power generation efficiencies in the case of the solar power generator 1 according to the embodiment shown in FIG. 1 (solid line) and in the cases of comparative examples (broken line: one-axis tracking type, dotted line: flat plate fixed type) are shown in FIG. 6.

FIG. 6 shows a relationship between an azimuth angle of the sun (horizontal axis) and the power generation efficiency (vertical axis). It is assumed that the solar power generator 1 makes the solar panel 10 follow the sun and an azimuth angle of the solar panel 10 coincides with the azimuth angle of the sun. The azimuth angle 0 indicates the south and the minus indicates the east, and the plus indicates the west respectively. The altitude and the azimuth of the sun on the spring equinox in central Japan are taken as an example. A power generation amount in the case where the solar panel faces the south and the elevation angle is 30 degrees when the sun culminates is defined as 100% of the power generation efficiency.

Specifications of the solar power generator used in the simulation are as follows. The elevation angle α at the time when the solar panel 10 faces the south is set at 30 degrees, and at that time, the distance from the universal joint 23 to the contact point between the periphery of the solar panel 10 and the base 2 is 8 m, the length F of the effective portion 21v of the supporting bar 21 is 4 in, and the distance L from the connection 14 to the contact point between the periphery of the solar panel 10 and the base 2 is 7 m.

The power generation efficiency in the case where the solar panel 10 faces the south and the elevation angle is fixed at 30 degrees and the power generation efficiency in the case where the elevation angle of the solar panel is fixed at 30 degrees and the azimuth of the solar panel is made to follow the azimuth of the sun are also shown in FIG. 6. The former one (dotted line) in FIG. 6 indicates the flat plate fixed type, and the latter one (broken line) in FIG. 6 indicates the one-axis tracking type.

Apparently, it is preferable that the solar panel faces the sun invariably and directly (perpendicularly). In order to do so, the length of the effective portion 21v of the supporting bar 21 may be changed and/or the fixation position of the supporting bar 21 to the solar panel 10 may be moved in the radial direction, for example.

A slant may be provided to the surface of the base 2 to change the height of the peripheral portion of the solar panel 10, thereby realizing the adjustment to make the solar panel face the sun directly.

If the base 2 has the leg portions, the leg portions may be used to change an inclination of the base 2.

In the above examples, the motor 30 is provided to rotate the solar panel 10, and the rotational driving force of the motor 30 is transmitted to the solar panel 10 through the universal joint 23 and the supporting bar 21.

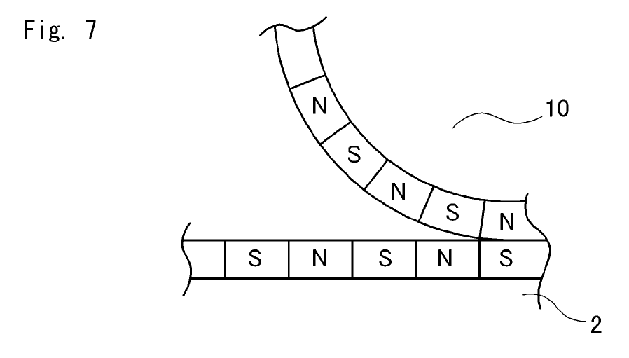

As another construction for rotating the solar panel 10, as shown in FIG. 7, fixed magnets of N and S may be arranged on the peripheral portion of the solar panel 10 and movable magnets may be arranged on the facing base 2 side. Thus, a linear motor may be constructed.

It is understood that the elevation angle of the solar panel 10 rotating on the surface of the base 2 can be adjusted by providing the concavity and the convexity or the slant portion on the surface of the base 2 in the above examples. That is, a cam structure using the base 2 as a cam and using the peripheral portion of the solar panel 10 as a follower section is formed.

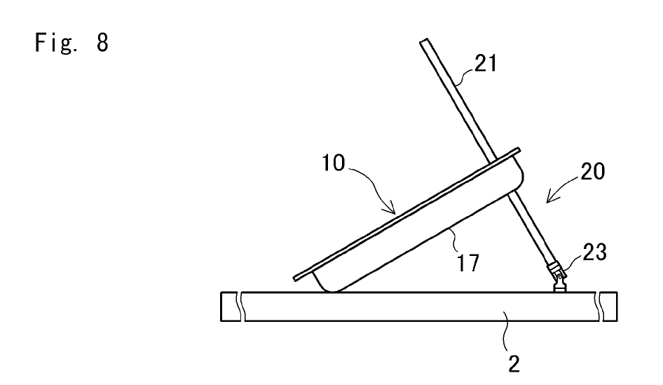

As shown in FIG. 8, a swelled portion 17 may be provided on a rear surface of the solar panel 10 and the swelled portion 17 may be brought into contact with the surface of the base 2, thereby using the swelled portion 17 as the follower section. Thus, the peripheral portion of the solar panel 10 does not contact the base 2.

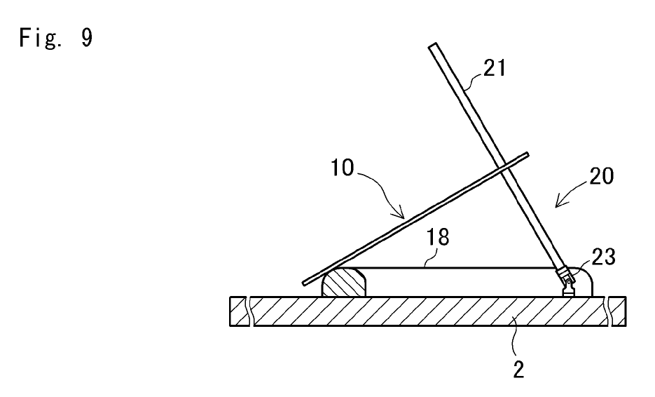

As shown in FIG. 9, a swelled portion 18 may be provided on the surface of the base 2 and a lower surface of the solar panel 10 may be brought into contact with a front face of the swelled portion 18, thereby distancing the peripheral portion of the solar panel 10 from the base 2.

Further, the swelled portion 17 may be provided on the rear surface of the solar panel 10 and the swelled portion 18 may be provided on the surface of the base 2 respectively such that the swelled portions 17, 18 contact each other to distance the peripheral portion of the solar panel 10 from the base 2.

By distancing the peripheral portion of the solar panel 10 from the base 2, the periphery reinforcement member 11 becomes unnecessary. Therefore, the photoelectric conversion elements can be arranged to a position as close to the peripheral portion as possible. In addition, the shape of the solar panel can be designed arbitrarily.

In the present embodiment, a follow control section (not shown) makes the solar panel 10 follow the sun such that the solar panel 10 is positioned at the optimum position with respect to the position of the sun. The follow control section should be preferably constructed to adjust the rotation amount of the solar panel 10 by sensor control using a photoelectric sensor or the like or by program control.

The present invention is not limited to the above-described embodiments of the present invention or the explanation thereof. The present invention includes various modifications within the scope easily devised by those skilled in the art without departing from the description of the claimed scope of the invention.

All the contents of the literatures, the laid-open patent publications, the patent gazettes and the like indicated in the specification are incorporated herein by reference.

### DESCRIPTION OF THE REFERENCE NUMERALS

1 SOLAR POWER GENERATOR
2 BASE
10 SOLAR PANEL
11 REINFORCEMENT SECTION
13 THROUGH HOLE
20 SUPPORTING SECTION
21 SUPPORTING BAR
23 UNIVERSAL JOINT
30 MOTOR

1. A solar power generator comprising:
a base, and
a solar panel rotatable in a circumferential direction, wherein
the solar panel has a follower section that contacts the base, and
the solar panel rotates with a lower end portion of the follower section in contact with the base.

2. The solar power generator as in claim 1, wherein a supporting section for azimuth direction tracking is attached to the solar panel, and the solar panel rotates around an attachment position of the supporting section.

3. The solar power generator as in claim 2, wherein one end of the supporting section is attached to the base rotatably, and the other end side of the supporting section is attached to the solar panel at a position deviated from the center of the solar panel.

4. The solar power generator as in claim 2, wherein the supporting section applies a rotational force to the solar panel.

5. The solar power generator as in claim 1, wherein a peripheral portion of the solar panel serves as the follower section.

6. The solar power generator as in claim 5, wherein a reinforcement section having wear resistance is formed in a range of the peripheral portion of the solar panel that contacts the base.

7. The solar power generator as in claim 6, wherein the solar panel has a round plate shape or an elliptical plate shape.

8. A solar panel used in a solar power generator, the solar panel comprising:
a reinforcement section that has wear resistance and that is formed in a peripheral portion of the solar panel.
